(19) United States
(12) Patent Application Publication
(10) Pub. No.: US 2023/0211873 A1
(43) Pub. Date: Jul. 6, 2023

(54) Method for Algorithmic Optimization of Active Flow Control Actuator Placement and Parameters

(71) Applicant: The Florida State University Research Foundation, Inc., Tallahassee, FL (US)

(72) Inventors: Fernando Zigunov, Tallahassee, FL (US); Farrukh Alvi, Tallahassee, FL (US)

(21) Appl. No.: 17/568,677

(22) Filed: Jan. 4, 2022

(51) Int. Cl. B64C 23/00; B64C 21/00

(52) U.S. Cl. CPC B64C 23/005; B64C 21/00

(57) ABSTRACT

Systems and methods are provided for experimentally determining optimized placement and operating conditions, e.g., amplitude, phase, or frequency, of active flow control actuators by executing an optimization routine to sequentially activate varying subsets of active flow control actuators of a plurality of active flow control actuators spatially distributed within a flow field, calculating a cost function of each of the subsets of sequentially activated active flow control actuators based on respective measurements of one or more parameters, e.g., integral variables or proxies to the integral variables, within the flow field by one or more sensors, and determining an optimal subset of active flow control actuators based on the respective cost functions of each of the subsets of sequentially activated active flow control actuators.

### STATEMENT REGARDING FEDERALLY SPONSORED RESEARCH OR DEVELOPMENT

This invention was made with government support under grant no. FA9550-17-1-0228 awarded by the Air Force Office for Scientific Research. The government has certain rights in this invention.

### FIELD OF USE

The present disclosure is directed to computerized methods for experimentally determining the best combination and locations of active flow control actuators for optimization of a desired cost function.

### BACKGROUND

Active flow control (AFC) is a promising technology that displays a high potential to improve aircraft performance and operational envelope, possibly playing a key role in the next generation of aircraft designs. It has been proven to be highly effective in changing flow topology and integral quantities such as drag, for flow control scenarios ranging from airfoils to bluff body wakes such as the ones produced by simplified models of vehicles. Active flow control also presents desirable characteristics, such as the ability to be disabled during certain flight conditions, greatly minimizing its negative effect on drag and lift, in contrast with passive flow control solutions such as vortex generators.

However, one of the many challenges that prevents wide usage of this technique in engineering applications is related to the difficulty in identifying the most effective locations and patterns for actuator placement as well as their operating conditions, e.g., amplitude and, for unsteady actuators, frequency and duty cycle, such that they have the most impact on the flow. For the more complex flow topologies found in practical aeronautical applications, the problem is still open. The challenge in predicting the outcomes produced by actuators is partly related to the complex interactions that occur at higher Reynolds numbers, and the non-linearity of the Navier-Stokes equations. Theoretical approaches based on stability analysis have been used until recently, in order to tackle this problem. Stability analysis of small perturbations of flow fields, for example, has been shown to have some degree of success in explaining phenomenological observations, especially at low Reynolds numbers.

A computational approach that has gained traction in recent years is the resolvent analysis which, like other competing approaches, also relies on moving the non-linearity source away from the formulation by considering it a “forcing term,” which limits the outcomes produced by the actuators to ones that cause minimal changes to the mean flow. Recent efforts on solving a full LES cavity model with synthetic jet-like forcing based on the resolvent modes do suggest, however, that the technique has potential to be useful in tackling the spatial sensitivity problem.

Despite the obvious advantages of computational approaches to solving the problem of effective flow control actuator placement, such as high scalability and reduced number of iterations in experimental testing, the aerodynamics community also needs an increased variety of practical solutions that together can move the active flow control technology forward to the engineering context. To satisfy these needs, many experimental researchers employed approaches that are loosely inspired by theory, referred to as “informed ad-hoc” herein. These techniques attempt to exploit well-known simple instabilities a flow might possess and are based on intuition and experience of the researchers involved. They have proven to be very useful in advancing the field of active flow control and demonstrated many times that it is possible to achieve net drag/power reduction and improved performance of other aerodynamic quantities such as jet noise or operational envelope. However, there is still a high degree of trial and error involved, since only a handful of actuator patterns can be deployed in any single study. Therefore, this approach could be greatly enhanced with emerging technologies like machine learning and model-free optimization, as long as a computer has access to changing the actuator pattern and its parameters with the wind tunnel in the loop.

Recent experimental studies showed that machine learning and optimization techniques can be applied directly in the experimental context, enabling the exploration of a large parameter space with thousands of data points in a short directed study. This type of experimental approach is currently more viable, in the economic sense, than its computational counterpart (i.e., simulating thousands of actuator combinations). One of the reasons for the cost imbalance is related to the enhanced multi-scale nature of the microactuator placement problem. For example, in order to accurately simulate the effect of the microactuator array in a given high Reynolds number flow field, it is critical to spatially resolve both the large flow scales related to the model scale as well as the microactuator scales, which currently is prohibitively expensive.

In view of the foregoing drawbacks of previously known systems and methods, there exists a need for a novel approach that is capable of experimentally exploring thousands of actuator array patterns experimentally in a short period of time. This would enable the timely attainment of an engineering solution to the flow control problem that can be used in many complex flow fields where the most effective active actuator locations are not intuitive.

### SUMMARY

Systems and methods are provided herein to overcome the drawbacks of previously-known technologies. In accordance with one aspect of the present invention, a system for determining optimized placement and operating conditions of active flow control actuators is provided. The system may include a plurality of active flow control actuators spatially distributed within a flow field, such that each of the plurality of active flow control actuators may be individually actuated, and one or more sensors for measuring one or more parameters within the flow field. In addition, the system may include a non-transitory computer readable medium programmed with instructions that, when executed by a processor of a computer, cause the computer to: execute an optimization routine to sequentially activate varying subsets of active flow control actuators of the plurality of active flow control actuators; calculate a cost function of each of the subsets of sequentially activated active flow control actuators based on respective measurements of the one or more parameters by the one or more sensors within the flow field; and determine an optimal subset of active flow control actuators based on the respective cost functions of each of the subsets of sequentially activated active flow control actuators.

At least one of position or one or more operating conditions of one or more active flow control actuators may vary across each subset of sequentially actuated active flow control actuators, such that the determined optimal subset of active flow control actuators includes a combination of optimal placement and optimal operating conditions. For example, the one or more operating conditions may include at least one of amplitude, phase, or frequency for each individual active flow control actuator. Moreover, each subset of sequentially actuated active flow control actuators may include one or more active flow control actuators, such that each of the one or more active flow control actuators includes a predefined position and one or more predefined operating conditions.

The varying subsets of active flow control actuators may be selected at random or in a predetermined manner by the optimization routine. Each active flow control actuator of the plurality of active flow control actuators may be a jexel comprising one or more microjets. In addition, the one or more parameters within the flow field measured by the one or more sensors may include integral variables or proxies to the integral variables within the flow field. For example, the integral variables may include at least one of drag, lift, noise, or energy consumption. The flow field may be representative of an aerodynamic body, e.g., an aerial vehicle, a land vehicle, an aquatic vehicle, or their components. Additionally or alternatively, the flow field may be representative of a turbomachine, e.g., a compressor, fan, or turbine.

In some embodiments, the optimization routine may include a genetic algorithm that, when executed: is initialized with a randomly chosen or a manually defined set of actuator configurations; sequentially activates a first generation of varying subsets of active flow control actuators of the plurality of active flow control actuators; calculates the cost function of each of the subsets of sequentially activated active flow control actuators based on the respective measurements of the one or more parameters by the one or more sensors within the flow field; and iteratively generates subsequent generations of varying subsets of active flow control actuators of the plurality of active flow control actuators based on the cost functions of each of the subsets of sequentially activated active flow control actuators of a previous generation to thereby determine the optimal subset of active flow control actuators.

Moreover, the genetic algorithm, when executed, may iteratively generate subsequent generations of varying subsets of active flow control actuators of the plurality of active flow control actuators by selecting an elite group of subsets from a current generation of the varying subsets of active flow control actuators based on the respective cost functions, mutating each subset of the elite group of subsets through a set of operations over one or more operating conditions of the plurality of active flow control actuators, and generating a subsequent generation of varying subsets of active flow control actuators based on randomly selected mutated subsets. For example, mutating each subset of the elite group of subsets may include executing operations selected from a list consisting of: change active flow control actuators count, change active flow control actuators addresses, change active flow control actuators frequency, change active flow control actuators phases, change active flow control actuators duty cycles, and change back-pressure.

Additionally, generating the subsequent generation of varying subsets of active flow control actuators based on randomly selected mutated subsets may include randomly selecting a pair of mutated subsets, copying a genome of a first mutated subset of the pair of mutated subsets, and swapping a randomly selected portion of the copied genome with a randomly selected portion of a genome of a second mutated subset of the pair of mutated subsets. The optimization routine further may include executing a clean-up operation on the optimal subset of active flow control actuators by iteratively deactivating an active flow control actuator of the optimal subset of active flow control actuators to assess contribution of the deactivated active flow control actuator.

In accordance with another aspect of the present invention, a computerized method for determining optimized placement and operating conditions of active flow control actuators is provided. For example, the computerized method may include executing an optimization routine to sequentially activate varying subsets of active flow control actuators of a plurality of active flow control actuators spatially distributed within a flow field; calculating a cost function of each of the subsets of sequentially activated active flow control actuators based on respective measurements of one or more parameters within the flow field by one or more sensors; and determining an optimal subset of active flow control actuators based on the respective cost functions of each of the subsets of sequentially activated active flow control actuators.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 illustrates an exemplary system for determining optimized placement and operating conditions of active flow control actuators in accordance with the principles of the present disclosure.

FIG. 2 shows some example components that may be included in an active flow control actuator optimization platform in accordance with the principles of the present disclosure.

FIG. 3 is a flow chart illustrating exemplary steps for determining optimized placement and operating conditions of active flow control actuators in accordance with the principles of the present disclosure.

FIG. 4A illustrates an exemplary model of a cylinder with a slanted afterbody constructed in accordance with the principles of the present disclosure.

FIG. 4B is a schematic of the components of a system using the model of FIG. 4A.

FIG. 4C illustrates a 4-hole probe path over a known baseline flow field.

FIG. 4D is a close up view of an exemplary jexel in accordance with the principles of the present disclosure.

FIG. 5 is a graph illustrating relative reduction in circulation measured in a parametric scan for manually selected jexel patterns in accordance with the principles of the present disclosure.

FIG. 6A is a graph illustrating convergence of circulation as a function of core radius, FIG. 6B is a graph illustrating convergence of circulation as a function of number of measurement points, and FIG. 6C illustrates long-term stability of circulation of the model in accordance with the principles of the present disclosure.

FIG. 7 illustrates evolution of reduction in circulation as a function of the genetic algorithm generation in accordance with the principles of the present disclosure.

FIG. 8A illustrates an exemplary clean-up process of obtained jexel patterns in accordance with the principles of the present disclosure.

FIG. 8B illustrates the measured change in circulation incurred by deactivation in the clean-up process of FIG. 8A.

FIGS. 8C and 8D illustrate the elected configurations for stereoscopic particle image velocimetry (SPIV) and measurements obtained for left and right vortex circulation in accordance with the principles of the present disclosure.

FIGS. 9A to 9C illustrate vorticity fields observed through SPIV for three configurations in accordance with the principles of the present disclosure.

FIG. 9D is a graph illustrating a comparison of the vorticity distribution as a function of radius for the right core between the vorticity fields of FIG. 9A and FIG. 9C.

### DETAILED DESCRIPTION

The present disclosure overcomes the drawbacks of previously-known systems and methods, e.g., machine learning approaches that do not address the actuator placement problem, by providing systems and methods for experimentally selecting the most effective spatial pattern of microactuators via optimization. The systems and methods described here are for experimentally finding the best combinations, locations, and operating conditions of active flow control actuators for optimization of a desired cost function (e.g., drag, lift, noise, etc.). The system implements an automated test bench that enables a computing platform running an optimization algorithm to individually toggle and parameterize active flow control actuators on-the-fly, without requiring prior knowledge of the details of the flow to be optimized. The proposed systems and methods make such a problem tractable, with many potential applications in the industry.

The disclosure will be described more fully hereinafter with reference to the accompanying drawings, in which example embodiments of the disclosure are shown. This disclosure may, however, be embodied in many different forms and should not be construed as limited to the example embodiments set forth herein. It will be apparent to persons skilled in the relevant art that various changes in form and detail can be made to various embodiments without departing from the spirit and scope of the present disclosure. Thus, the breadth and scope of the present disclosure should not be limited by any of the above-described example embodiments but should be defined only in accordance with the following claims and their equivalents. The description below has been presented for the purposes of illustration and is not intended to be exhaustive or to be limited to the precise form disclosed. It should be understood that alternate implementations may be used in any combination to form additional hybrid implementations of the present disclosure. For example, any of the functionality described with respect to a particular device/component may be performed by another device/component. Further, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments.

Certain words and phrases are used herein solely for convenience and such words and terms should be interpreted as referring to various objects and actions that are generally understood in various forms and equivalencies by persons of ordinary skill in the art.

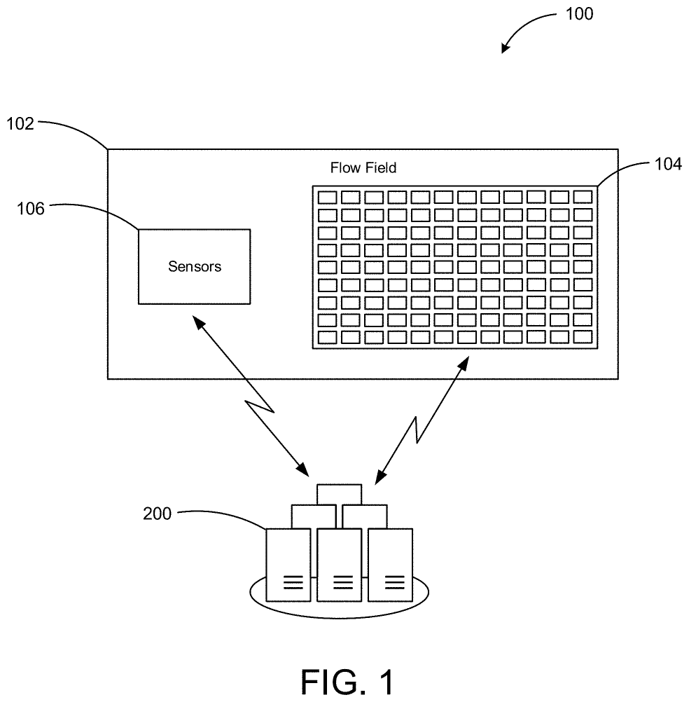

FIG. 1 illustrates an exemplary system for determining optimized placement and operating conditions of active flow control actuators. As shown in FIG. 1, system 100 may include an array of a plurality of active flow control actuators 104 spatially distributed within flow field 102. Flow field 102 may be constructed to be representative of any body for which optimization of active flow control actuators is sought to be determined. For example, flow field 102 may be representative of an aerodynamic body, e.g., an aerial vehicle, a land vehicle, an aquatic vehicle, or their component parts such as a wing of an airplane, etc. Alternatively, flow field 102 may be representative of a turbomachine, e.g., a compressor, fan, turbine, etc.

Each active flow control actuator of plurality of active flow control actuators 104 within the array may be operatively coupled to active flow control actuator optimization platform 200 and may be individually actuatable, such that varying subsets of active flow control actuators of plurality of active flow control actuators 104 may be sequentially actuated, e.g., independent of the non-actuated active flow control actuators. For example, a subset may include one or more active flow control actuators at preselected positions within the array, such that the position of one or more active flow control actuators forming a subset may vary across subsets. In addition, the operating conditions, e.g., amplitude, phase, or frequency, of each active flow control actuator forming a subset may vary across subsets. Accordingly, two different subsets of active flow control actuators may include the same or different number of active flow control actuators, the same or different positions of active flow control actuators, the same or different operation conditions, or any combination thereof. Moreover, the number, position, and/or operating conditions of the active flow control actuators of each subset may be selected at random or may be manually defined by platform 200. As defined herein, each active flow control actuator of the plurality of active flow control actuators may be a “jexel,” which may include one or more microjets. For example, a jexel may include one, two, three, four, or more individual microjets.

As shown in FIG. 1, system 100 further may include one or more sensors/probes 106 operatively coupled to platform 200 for measuring one or more parameters within flow field 102, e.g., responsive to actuation of the active flow control actuators within flow field 102. For example, sensors 106 may directly measure one or more integral variables, e.g., drag, lift, noise, or energy consumption, within flow field 102 responsive to actuation of the active flow control actuators, and/or sensors 106 may measure one or more proxies of an integral variable, such as circulation which is a proxy of aerodynamic drag, as described in the study summarized below. As will be understood by a person having ordinary skill in the art, sensors 106 may measure additional integral variables and/or respective proxies that may be of interest to an industry-specific end user. Moreover, sensors 106 may generate signals indicative of the measured parameters for transmission to platform 200.

As shown in FIG. 1, array of plurality of active flow control actuators 104 and sensors 106 may be communicatively coupled to active flow control actuator optimization platform 200, e.g., either by wired connection or via a network. For example, the network may include any one, or a combination of networks, such as a local area network (LAN), a wide area network (WAN), a telephone network, a cellular network, a cable network, a wireless network, and/or private/public networks, such as the Internet. Additionally, the network may support communication technologies, such as TCP/IP, Bluetooth, cellular, near-field communication (NFC), Wi-Fi, Wi-Fi direct, machine-to-machine communication, man-to-machine communication, and/or a vehicle-to-everything (V2X) communication. Active flow control actuator optimization platform 200 may be located on one or more servers, e.g., on a cloud server, and/or embedded in a computer.

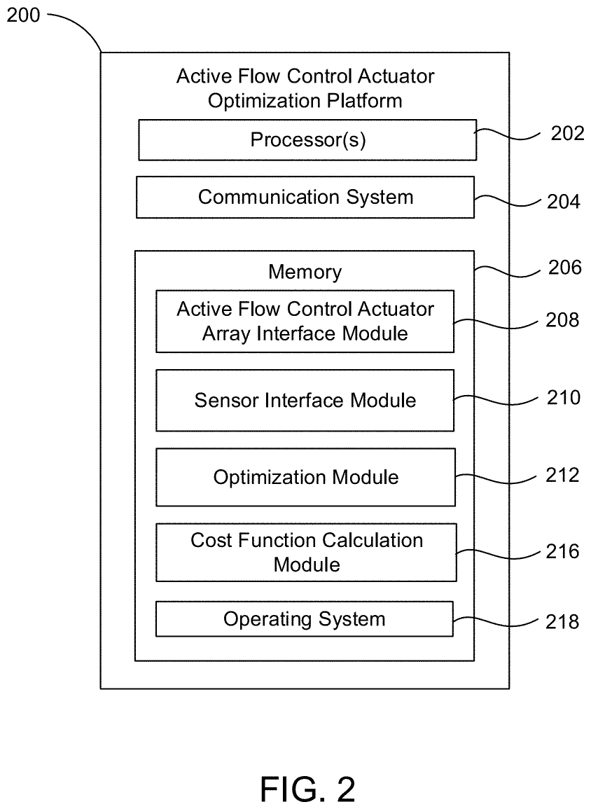

Referring now to FIG. 2, components that may be included in active flow control actuator optimization platform 200 are described in further detail. Active flow control actuator optimization platform 200 may include one or more processors 202, communication system 204, and memory 206. Communication system 204 may include a wired or wireless transceiver that allows active flow control actuator optimization platform 200 to communicate with the array of plurality of active flow control actuators 104 and sensors 106 within flow field 102. The wireless transceiver may use any of various communication formats, such as, for example, an Internet communications format, or a cellular communications format.

Memory 206, which is one example of a non-transitory computer-readable medium, may be used to store operating system (OS) 218, active flow control actuator array interface module 208, sensor interface module 210, optimization module 212, and cost function calculation module 216. The modules are provided in the form of computer-executable instructions that may be executed by processor 202 for performing various operations in accordance with the disclosure.

Active flow control actuator array interface module 208 may be executed by processor 202 for interfacing with plurality of active flow control actuators 104. As described above, each active flow control actuator of plurality of active flow control actuators 104 may be individually actuated, and the operating conditions of each active flow control actuator may be selectively actuated. Accordingly, active flow control actuator array interface module 208 may individually actuate each active flow control actuator of plurality of active flow control actuators 104 at predefined operating conditions in a manner in accordance with the optimization routine executed by optimization module 212 described in further detail below.

Sensor interface module 210 may be executed by processor 202 for interfacing with sensors 106. For example, sensor interface module 210 may cause sensors 106 to measure one or more parameters within flow field 102, e.g., integral variables such as drag, lift, noise, or energy consumption, or proxies thereof, responsive to actuation of plurality of active flow control actuators 104 via active flow control actuator array interface module 208. Moreover, sensor interface module 210 may receive one or more signals generated by sensors 106 indicative of the measured parameters for further processing.

Optimization module 212 may be executed by processor 202 for executing an optimization routine, e.g., an algorithm, for sequentially activating varying subsets of active flow control actuators of plurality of active flow control actuators 104 via active flow control actuator array interface module 208 to determine optimized placement and operating conditions of active flow control actuators within flow field 102. Optimization module 212 may select which active flow control actuators of plurality of active flow control actuators 104 to include in a given subset, and further may select the operating condition, e.g., amplitude, phase, or frequency, of each active flow control actuator to be actuated. The active flow control actuators and their respective operating conditions of each subset may be selected randomly or in a predetermined manner by optimization module 212. Moreover, based on the cost function of each subset calculated by cost function calculation module 216, as described in further detail below, optimization module 212 may create subsequent subsets of active flow control actuators to be sequentially actuated via active flow control actuator array interface module 208, such that the cost functions converge toward an optimal subset of active flow control actuators having an optimal configuration, e.g., number, position, and/or operative conditions of active flow control actuators.

As described in the study summarized below, the optimization routine may include, e.g., a genetic algorithm. For example, upon execution by optimization module 212, the genetic algorithm may be initialized with a randomly chosen or a manually defined subset of active flow control actuator configurations, e.g., number, position, and/or operative conditions of active flow control actuators, then may sequentially activate a first generation of varying subsets of active flow control actuators of plurality of active flow control actuators 104. Based on the calculated cost functions of each of the subsets of sequentially activated active flow control actuators of the prior generation, e.g., the first generation, the genetic algorithm may iteratively generate subsequent generations of varying subsets of active flow control actuators of plurality of active flow control actuators 104, such that the calculated cost functions of each of the subsets of sequentially activated active flow control actuators of each subsequent generation converge toward the optimal subset of active flow control actuators.

For example, the genetic algorithm may iteratively generate subsequent generations of varying subsets of active flow control actuators by selecting an elite group of subsets from a current generation of the varying subsets of active flow control actuators based on the respective cost functions, mutating each subset of the elite group of subsets through a set of operations over one or more operating conditions of the active flow control actuators, and generating a subsequent generation of varying subsets of active flow control actuators based on randomly selected mutated subsets.

Moreover, the optimization routine may include a clean-up step for further optimization. For example, the clean-up step may include deactivating one active flow control actuator at a time from the determined optimal subset of active flow control actuators, and actuating the remaining active flow control actuators to determine the contribution of the deactivated active flow control actuator. The iterative deactivation allows for definition of which active flow control actuators are effectively contributing to the results obtained, versus active flow control actuators that were left active because their contribution to the overall performance is neither positive nor negative, in which case they are only consuming actuation power.

As will be understood by a person having ordinary skill in the art, the optimization routine may include algorithms other than a genetic algorithm, and further may include, e.g., machine learning, a neural network, and/or other optimization algorithms.

Cost function calculation module 216 may be executed by processor 202 for calculating the cost function (e.g., drag, lift, noise, etc.) of each subset of active flow control actuators based on respective measurements of the one or more parameters by sensors 106 within flow field 102 responsive to actuation of the subset within flow field 102. Thus, based on the cost function of each subset calculated by cost function calculation module 216, optimization module 212 may create subsequent subsets of active flow control actuators to be sequentially actuated via active flow control actuator array interface module 208, such that the cost functions of each subsequent subset calculated by cost function calculation module 216 converge toward the optimal subset of active flow control actuators. Accordingly, optimization module 212 may include a stopping condition, e.g., when the optimal subset of active flow control actuators has been determined.

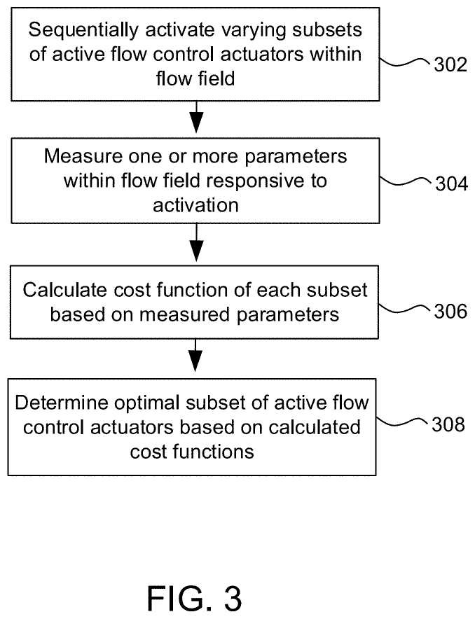

Referring now to FIG. 3, exemplary method 300 for determining optimized placement and operating conditions of active flow control actuators is provided. At step 302, varying subsets of active flow control actuators of plurality of active flow control actuators 104 within flow field 102 are sequentially actuated, e.g., via active flow control actuator array interface module 208, in accordance with the optimization routine executed by optimization module 212. At step 304, for each subset of active flow control actuators actuated during step 302, one or more parameters within flow field 102 are measured by sensors 106, e.g., via sensor interface module 210, responsive to actuation of the respective subset of active flow control actuators within flow field 102. For example, sensors 106 may measure one or more integral variables of interested to an industry-specific end user, or respective proxies thereof. In addition, sensors 106 may generate one or more signals indicative of the one or more parameters measured by sensors 106.

At step 306, for each subset of active flow control actuators actuated during step 302, the cost function may be calculated, e.g., via cost function calculation module 216, based on the one or more parameters measured by sensors 106 at step 304. Steps 302 to 306 may be repeated over and over, until the cost function calculated at step 306 converges toward the optimized configuration of active flow control actuators, e.g., number, position, and/or operating conditions of each individual active flow control actuator, and the optimal subset of active flow control actuators is determined at step 308.

### Experimental Results

In this study, a novel technique to experimentally determine the most effective actuator locations in an active flow control context is implemented and its efficacy demonstrated through detailed measurements of flow response to control. The platform developed provides an engineering solution to the problem of actuator placement with commonly available components, by using an optimizing algorithm to explore the parameter space with a wind tunnel in the loop. The optimizing algorithm, specifically a genetic algorithm, sequentially activates the microactuators in different patterns (subsets) and evaluates a cost function related to each pattern through measurements in the flow field, which enables the exploration of thousands of actuator patterns, thereby rapidly converging to viable configurations. The platform was tested in a canonical bluff body flow, the cylinder with a slanted afterbody at a slant angle of Φ=45°, which is known to produce a high drag wake. The novel optimization process found an actuator arrangement that is markedly different from those obtained through “experience-informed” actuator arrangements. This non-intuitive, but optimal solution reduced the vortex circulation, which is a surrogate for drag reduction, by 10.6%, which was three times the maximum circulation reduction through traditional actuator arrangements. Moreover, a posterior clean-up procedure revealed a pattern that can potentially be interpreted in terms of fundamental flow control physics. The substantial improvement in AFC-enabled performance makes this platform and approach worth exploring for other aerodynamic applications.

A=Area of the vorticity integration [m²].

C_{D}=Drag Coefficient [−]

C_{μ}=Microjet momentum coefficient [−]

C_{π}=Microjet power coefficient [−]

\vec{d}s=Differential vector along the path of integration [m]

D=Cylinder diameter [m]

f=Actuator frequency [Hz]

J=Cost function [−]

L=Slanted Section Length [m]

nₚₜₛ=Number of points in the circulation contour [−]

P=Microjet mechanical power [W]

P_{B}=Microjet back-pressure [psig]

r=Radius of the circulation contour [m]

Re_{D}=Reynolds number based on cylinder diameter [−]

\vec{V}=Velocity vector [m/s]

V_{∞}=Free stream velocity [m/s]

x=Spanwise coordinate [m]

y=Vertical coordinate [m]

z=Streamwise coordinate [m]

ΔΓ=Change in vortex circulation [m²/s]

Γ=Vortex circulation [m²/s]

Γ₁=Geometrical vortex core tracking quantity [−]

ω_{z}=Dimensional vorticity [l/s]

Ø=Slant Angle [deg]

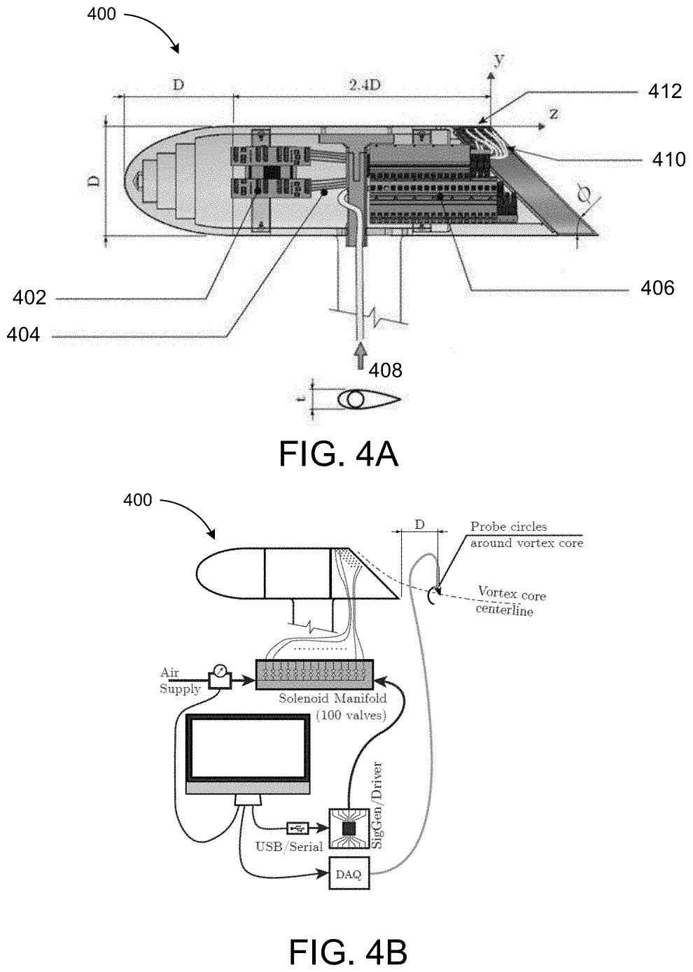

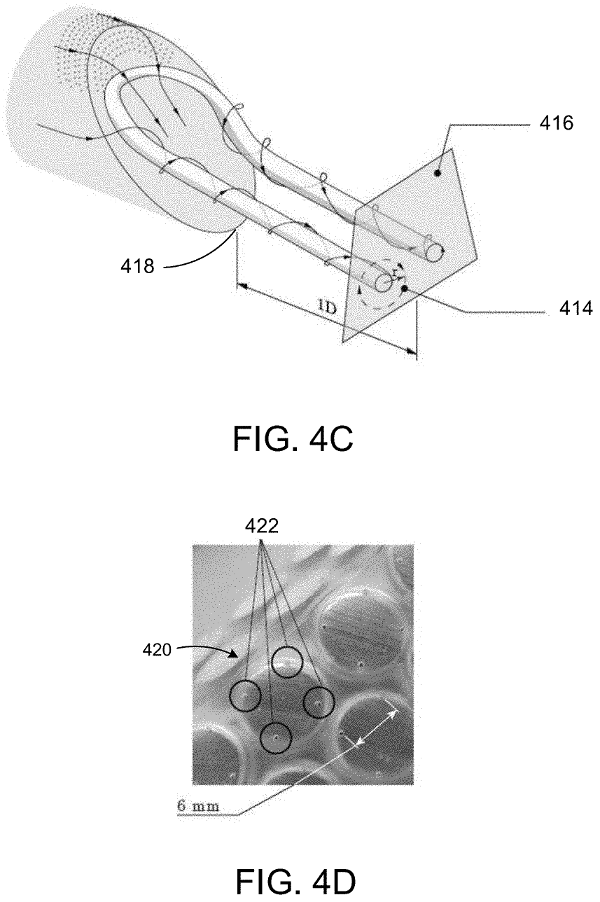

The experiments described in this study were performed in the Low Speed Wind Tunnel facility (LSWT) at the Florida Center for Advanced Aeropropulsion (FCAAP) of FAMU-FSU College of Engineering. The facility is an open-circuit wind tunnel with a square test section of 0.762 m side and is capable of free stream velocities of V_{∞}=2.5 m/s to V_{∞}=70 m/s. FIG. 4A illustrates the model employed in this study, a cylinder with a slanted afterbody. This model was chosen because it presents a complex bluff body wake that contains a strong pair of counter-rotating vortices. As shown in FIG. 4A, model 400 includes signal generator 402, cabling to solenoids 404, solenoid manifold 406, air inlet 408, tubing 410, and jexel array 412 including 59 individually addressable actuators.

The model diameter was D=0.146 m, with a straight section of length 2D and a blunt nose with an ellipsoid shape of 2:1 ratio. The model rear slant angle was Ø=45°, which is known to produce a very strong counter-rotating vortex pair and a drag coefficient of C_{D}=0.6. The free stream velocity was chosen to be V_{∞}=10.3 m/s, which results in a Reynolds number based on the cylinder diameter of Re_{D}=1×10⁵.

The slanted cylinder was supported by a steel tube, necessary to pass the cables and pneumatic tubing to control and feed the microjets. The tube was shrouded with a NACA0020 airfoil of thickness 22 mm, in order to minimize its impact in the wake of the model. The wake of this model is described in detail with three-dimensional PIV measurements in Zigunov, F., Sellappan, P., and Alvi, F. S., “Reynolds number and slant angle effects on the flow over a slanted cylinder afterbody,” Journal of Fluid Mechanics, Vol. 893, 2020. https://doi.org/10.1017/jfm.2020.214.

The platform developed in this study was designed to enable the control computer used for optimization to have access to changing the actuator configuration with as much freedom as possible. In order to do so, the system illustrated schematically in FIG. 4B was built. The optimization computer, running a Matlab® genetic algorithm script, sends serial commands to a 2-D CNC traversing mechanism that holds a Turbulent Flow Instrumentation four-hole (“Cobra”) probe. The four-hole probe is, for every case, traversed around the right (as seen from upstream of the model) vortex core centerline in circular path 414 on spanwise plane 416 with 40 points, as shown in FIG. 4C. The choice of number of points is described in further detail below.

The probe was positioned at 1D downstream of trailing edge 418. Only one vortex was traversed, to reduce the experimental time necessary to compute the cost function. Each data point comprises 1.6 seconds of data, and the four-hole probe pressure measurements allow for the computation of the time-averaged three-dimensional velocity vector at each traversed point. This enables for the measurement of the vortex circulation, by integrating:

Γ=∫_{C}\vec{V}·\vec{d}s

Circulation has been shown to be directly proportional to the drag coefficient for the slanted cylinder model for various slant angles with a negligible zero-crossing of C_{D0}=0.01, meaning changes in circulation should translate directly to changes in drag. The circulation was elected as the cost function variable, instead of more direct choices such as force balance measurements, due to the higher accuracy of the measurements offered by the four-hole probe. The measurement uncertainty in circulation is estimated to be 0.5%. The cost function then was defined as:

$$J = \frac{{Γ}_{jexel} - {Γ}_{baseline}}{{Γ}_{baseline}} = \frac{Δ Γ}{Γ} ∝ \frac{Δ {C}_{D}}{{C}_{D}}$$

Where Γ_{baseline} is the vortex circulation with all “jexels” off and Γⱼₑₓₑₗ is the circulation for the particular “jexel” pattern being analyzed. The optimization computer had access to the air supply pressure through a digitally controlled pressure regulator (Bellofram 961-085-000). It also had access to 100 solenoid valves (Matrix Pneumatix DCX.321.1E3C2.24) connected to the pressurized air manifold. The valves are capable of toggling the air flow at frequencies up to 200 Hz, which was set as the upper limit of the frequency range accessible to the optimizer. Each solenoid was controlled by an individually generated, parameterized square waveform produced by the custom electronics board, e.g., signal generator 402, shown in FIG. 4A. The board, driven by a PIC32MZ2048EFH144 microcontroller, was custom designed to fit inside the aerodynamic model, given the necessity of an individual power cable for every solenoid that would be impossible to route through the supporting strut tube. The microcontroller is capable of simultaneously generating 108 independent digital waveforms sampled at a rate of 50 kS/s that can be parameterized through a USB-Serial connection to the optimization computer.

A back-plate containing the micro-actuators, e.g., jexel array 412, was manufactured through the SLA 3D printing process, as shown in FIG. 4A. It contained 59 pneumatic channels, each of which contains four 0.4 mm diameter microjets arranged in a square pattern of 6 mm side. The plate was manufactured on a Formlabs Form 2 3D printer, and extreme care was taken to ensure every single jet was completely clear of resin prior to post-cure. Each pneumatic channel will be referred herein as a “jexel,” which is short for “jet pixel,” in a reference to how computers build image patterns in a similar way we seek to define the most effective pattern of jets in the model surface. FIG. 4D illustrates an exemplary “jexel”, e.g., jexel 420. For purposes of this study, the “jexel” is defined as a group of four microjets, e.g., microjets 422, which was a trade-off design decision taken to cover a larger surface of the aerodynamic model with the same number of pneumatic channels; however, as will be understood by a person having ordinary skill in the art, a “jexel” may be defined as a group of another amount of microjets.

An optimizer based on the novel Genetic Algorithm (GA) described herein was implemented in this study. The usage of a GA instead of other optimization techniques was motivated by the very large parameter space to be covered and the presence of significant uncertainty in the measurements. The GA is, in general, an algorithm that is robust to these aspects of the parameter space. A population size of 30 individuals was chosen due to the long time necessary to evaluate the cost function. The standard operations of the GA, e.g., Elitism, Mutation and Crossover, were applied every generation. An elite fraction of 40% was chosen and the mutations randomly added/removed/shuffled “jexels” and their properties.

Specifically, the particular implementation of the GA used in this study defined a case genome with one continuously varying parameter for the “jexel” back-pressure, 0<P_{B}<10 psi, and 4 arrays of parameters of variable length: JxAddresses stores the addresses (1-59) of the “jexels” activated for that case; JxPhases stores the individual phase delays with respect to a reference time, JxDuties stores the duty cycle used for each “jexel”. A single frequency, JxFrequency, was used for all “jexels”. All arrays had the same length, which corresponds to the number of “jexels” activated for the corresponding case. A minimum length of 5 and a maximum length of 25 was defined, limited by the maximum current capacity of the electronic board designed.

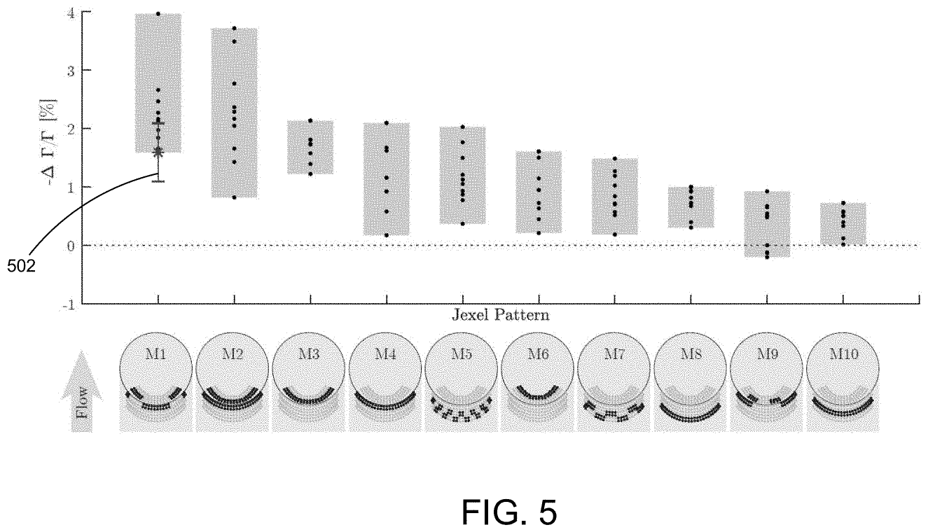

The genetic algorithm was then fed an initial population of 30 “jexel” configurations, which were the best cases obtained after a parametric scan of manually selected patterns that followed the classical “informed ad-hoc” approach. Specifically, in order to initialize the GA_{±} with a meaningful starting point and ensure the patterns selected were free of hindsight bias, the first experiment performed was a parametric scan with manually selected “jexel” patterns. The parameter scan was coarse, including five frequencies (f=5, 50, 100, 150, 200 Hz) and two back-pressures (P_{B}=5, 10 psi) for each pattern. The duty cycle was kept fixed at 50% and the phase angle was fixed at 0°. A total of 17 patterns were examined, and the 10 best patterns were organized by their relative circulation reduction with respect to the baseline case, as shown in FIG. 5.

FIG. 5 is a graph illustrating relative reduction in circulation measured in a parametric scan for manually selected jexel patterns. In the plot area of FIG. 5, each experiment is represented by a black dot, where the uncertainty is shown as error bar 502 for reference. The gray box highlights the extents of the changes observed by varying the parameters previously described. The best two patterns potentially excited the shear layer prior to separation at the sharp edge of the model.

As shown in FIG. 5, the configuration M1 had the best performance for the actuation frequency of f=200 Hz and back-pressure of P_{B}=10 psi; however, the performances of M1 and M2 are indistinguishable given the blue uncertainty bar of 0.5%. The configurations M3 and M4, however, only accomplish half as much as M2, indicating it is their combined effect that leads to M2's performance. The configurations M8 and M10, where the blowing occurs at the boundary layer in a line of “jexels,” had a less significant effect. M5 and M7, on the other hand, seemed to be slightly more effective than M8 and M10 with their staggered arrangement. It is possible that their effect on the boundary layer can be compounded to improve M2.

In general, the higher frequency cases scored larger circulation reductions; however, it was later found, as described in further detail below, that the most likely reason for the improved reduction in circulation is the increased momentum flux of each “jexel,” as the solenoid reaction time became an increasingly larger fraction of the cycle period. At this stage, however, a steady blowing case was not examined. It is worthwhile mentioning, however, that even this manual optimization phase can be extremely useful in the wind tunnel testing context, since hundreds of configurations can be planned and rapidly deployed in a short experimental campaign. From the 170 cases explored, the best 30 configurations (including their frequencies and back-pressures) were fed as the initial generation of the GA. The population was kept constant at 30 individuals per generation. For each individual, the cost function was measured and evaluated, using the equation described above.

Moreover, the baseline circulation, Γ_{baseline}, was re-evaluated with all “jexels” deactivated after every 10 cases to make sure any low-frequency trends in the baseline case were mitigated. A moving average of 10 baselines was used to reduce sudden changes between the individuals' cost functions.

For every generation, the genetic algorithm performed the operations described below. The specific values of the probabilities and probability distributions were arbitrary and were kept unchanged during the experiment.

Elitism: 40% (12) of the best individuals (least J) were selected as “elite” individuals and carried over to the next generation.

Mutation: Each elite individual was then mutated. Mutation would perform the following operations:

Change jexel count: With a probability of 30%, the number of “jexels” would be changed. If change occurred, one “jexel” would be added to or removed from all arrays with 50% chance.

Change jexel addresses: With a probability of 30%, the addresses of N “jexels” would be changed. The random number N, between 1 and 6, would be picked from a uniform distribution and random entries of the JxAddresses array would be swapped to unassigned addresses.

Change jexels frequency: With a probability of 50%, the frequency f of all “jexels” would be added to a Gaussian random number of zero mean and standard deviation of 30 Hz. To ensure 0≤f≤200 Hz, another random number would be picked if the frequency was out of bounds until 0≤f≤200 Hz.

Change jexel phases: With a probability of 50%, the phases of N “jexels” would be changed. The random number N, between 1 and 6, would be picked from a uniform distribution and random entries of the JxPhase array would be added to a Gaussian random number of zero mean and standard deviation of 60 deg. Proper phase wrapping was performed.

Change jexel duty cycles: With a probability of 50%, the duty cycles of N “jexels” would be changed. The random number N, between 1 and 6, would be picked from a uniform distribution and random entries of the JxDuties array would be added to a Gaussian random number of zero mean and standard deviation of 30%. The duty cycle was enforced to be between 0 and 100%.

Change back-pressure: With a probability of 30%, the backpressure P_{B} of all “jexels” would be added to a Gaussian random number of zero mean and standard deviation of 3 psi. To ensure 0≤P_{B}≤10 psi, another random number would be picked if the back-pressure was out of bounds.

Crossover: The remainder 60% (18) individuals were “children” of the mutated elite individuals generated with the two previous steps. Crossover would be performed by following the steps below:

Choose parents: Two random individuals from the 12 mutated elite individuals would be selected for the crossover operation.

Jexel count definition: Since each parent is expected to have a different number of “jexels,” one of the parents was picked randomly to define the length of the child's genome (i.e., the length of the JxXXX arrays).

Cross-over jexels: The genome of the selected parent was copied to the child's genome. Then, half of the “jexels” would be randomly selected and swapped by the other parent's jexels. Non-repeatability of the “jexel” addresses was enforced.

Back-pressure interpolation: The back-pressure was interpolated between the two parents with a randomly chosen weight 0<w<1, such that P_{B,C}=WP_{B,P1}+(1−W)P_{B,P2}.

Evaluation: All the new individuals in the current generation would be evaluated by measuring Γ and computing J.

This novel genetic algorithm was performed every generation. From Generation 30 onwards, however, in order to prevent the aggressively random parameters from changing the population too much, the best 3 elite individuals stopped being mutated by the algorithm.

The problem explored in this study is of a combinatorial nature: choosing any number of “jexels” between 5 and 25, out of the available 59 positions, yields 86×10¹⁶ possible patterns. By including the possible values for the remaining variables, a parameter space of the size of 10²¹ was expected. For the experimental time available, it was expected that about 3000 patterns would be viable to explore, which is a tiny fraction of the parameter space. To deal with this issue, the parameters on the GA, as described above, were on the aggressive side to foster breadth of the search. The results obtained, however, suggest that the parameter space is somewhat smooth and that some degree of superposition might be applicable, e.g., certain features of the patterns found seem to have separable functionality. For the best configuration obtained through the GA and a few of its variants, Stereoscopic Particle Image Velocimetry (SPIV) was performed at spanwise plane 416 at the same downstream location as the four-hole probe (1D from trailing edge 418, as shown in FIG. 4C). SPIV served the purpose of confirming that changes observed with the four-hole probe were accurate depictions of the changes in the vortex characteristics and provide a supporting measurement for the results obtained. It was performed with a LaVision PIV system, with two sCMOS cameras looking at the plane of interest from upstream at an angle of 44°. The cameras were fitted with a Nikkor 50 mm lens and a Scheimpflug adaptor. The laser sheet was produced by a Quantel Evergreen Nd:YAG double-pulse laser with a pulse energy of 200 mJ, and the PIV images were acquired at 15 Hz. Acquisition, storage, de-warping, stereo self-calibration and post-processing of the images into vector fields was performed in the LaVision 8.4 software. Sets of 500 vector fields were obtained for each case examined, achieving a vector spacing of 0.62 mm/vector with a 32×32 px correlation window size and 75% overlap. The uncertainty of the mean vectors obtained was <2%.

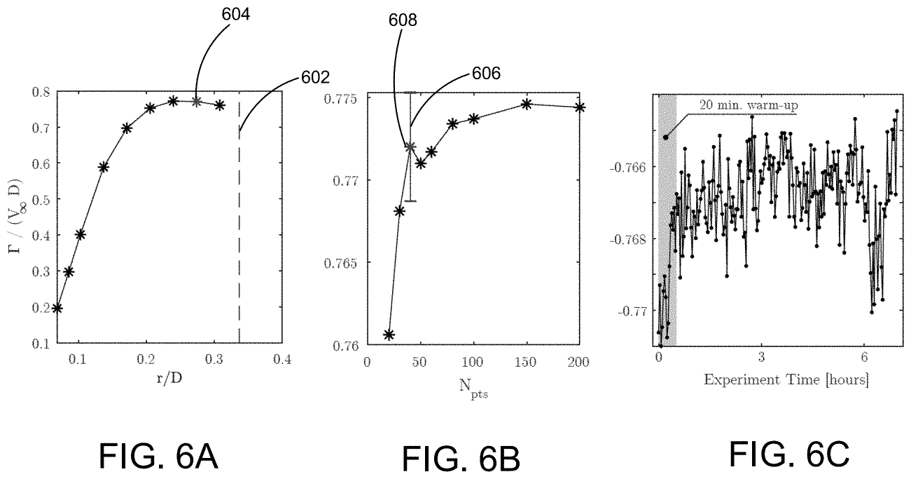

To determine the number of points and the radius of the circle where the circulation is being evaluated in the physical domain, a set of experiments was performed to assess the convergence of this metric as a function of these two variables (nₚₜₛ and r). The measurements of baseline circulation are shown as a function of these parameters in FIGS. 6A-6C. As shown in FIG. 6A, convergence of the circulation as a function of core radius occurs at about r/D≈0.25. Dashed line 602 in FIG. 6A is the half-distance between vortex cores. Point 604 is the parameter selected for optimization experiments. As a function of number of measurement points, the circulation shown in FIG. 6B is already close to its converged value even for nₚₜₛ=20, as can be noted by the magnified circulation scale in FIG. 6B and the 0.5% error bar 606. The number of points nₚₜₛ in which circulation is computed should be minimized to increase the number of experiments that can be accomplished during a given amount of time, and therefore the parameters chosen for the experiments presented in this study are r/D=0.274 and nₚₜₛ=40. Point 608 is the parameter selected for optimization experiments.

When performing optimization in real systems where long term experiments will be conducted, extra care must be taken to ensure the conditions under which the cost function is being computed are not changing too much over large time periods. If this is the case, the optimization algorithm cannot differentiate between changes in the cost function achieved by real improvements from variations in the environment that also affect the cost function. Obviously, this can negatively affect the optimization process and lead to null results. Therefore, it is imperative to assess this effect and the viability of implementing the four-hole pitot probe setup to measure circulation. An experiment to quantify the drift in the facility over time was therefore performed. The wind tunnel was started at the fan frequency that produced the desired Reynolds number (Re_{D}=1×10⁵) and the traversing mechanism was set up to acquire 40 samples of velocity evenly distributed along a circumference of radius r/D=0.274 for the computation of circulation, since it was observed that these parameters are sufficient for the convergence of the quantity of interest.

A complete traversal of the 40 points took about 126 seconds per case, where 1.6 seconds per point corresponded to data acquisition and the remaining delay (˜1.5 s) was introduced to let the mechanism reach the target position, preventing acquisition while in motion. This interval affords 685 data points per day of experimentation, which was deemed sufficient for reaching an engineering solution to this problem. In this experiment, no “jexels” were activated, instead simply observing the variations in the baseline over the course of 7 hours. The results obtained, e.g., the long-term stability of the circulation of the model, are illustrated in FIG. 6C. As shown in FIG. 6C, a warm-up period of about 20 minutes is observed, where the data is believed to have increased variability while the mechanical and electrical components of the fan and its driver electronics reach thermal equilibrium, slightly changing the free stream velocity. After the warm-up period, the measured circulation has a standard deviation of 0.15% of the mean value (excluding the shaded zone), meaning an uncertainty bar of 0.5% covers three standard deviations associated with the low frequency variations in the facility. The circulation mean value of the baseline case obtained by the four-hole probe measurement, Γ_{4H}/(V_{∞}D)=0.767, was very close to the value later obtained in PIV measurements Γ_{PIV}/(V_{∞}D)=0.79, where Γ_{PIV}=∫_{A} ω_{z}dA was obtained by vorticity integration.

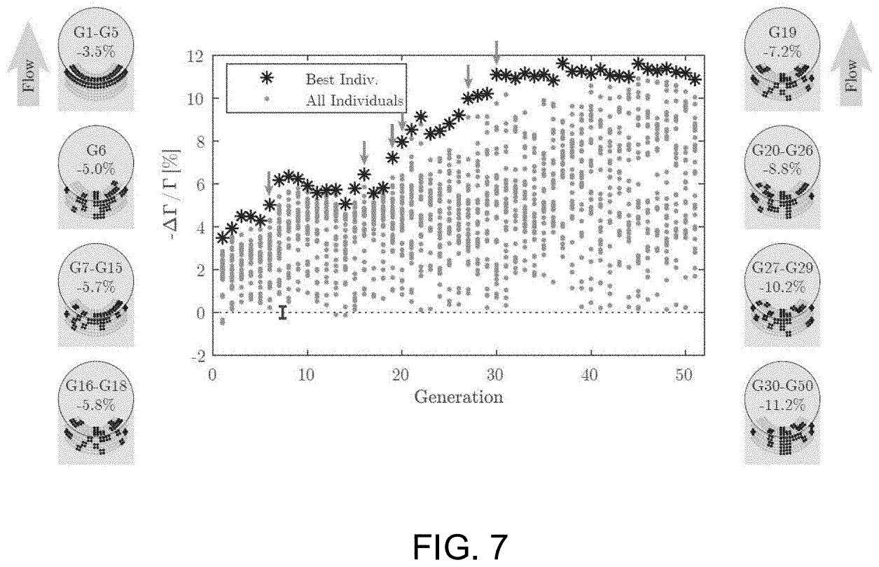

The GA described above was deployed in this phase of the experiments. The evolution of the results for 51 generations, corresponding to a total of 1530 “jexel” patterns, is summarized in FIG. 7. The manually optimized seed population of Generation 1 (G1) was re-evaluated, this time observing a circulation change of 3.5% for the seed configuration M2. As discussed, this is the same change observed in the manual optimization step, given the uncertainty in the measurements. This configuration persisted as the best configuration from G1 to G5. In G6 the first “breakthrough” was observed (denoted by downward arrow), and subsequent “breakthroughs” were observed in G15, G19, G20, G27 and G30 (denoted by downward arrows). Due to the random nature of the GA, the patterns produced look very noisy and indistinguishable from each other at a first glance. However, a few observations can be made. First, the GA seemed to favor patterns that involve activating some of the “jexels” just upstream of the slant edge, along the cylindrical surface, mostly at the center plane. Secondly, “jexels” just after the slant edge, farther from the center plane, also seemed to be deactivated more often. Finally, the GA preferred actuation frequencies close to the upper limit (200 Hz). Even though the patterns look noisy, there is a clear motivation to understand them further, since their performance was three times better than the best manually selected configuration, with a similar number of active “jexels”.

A clean-up step is as important as the GA optimization step when the cost function does not incentivize the algorithm to seek solutions with a lower actuator count. Here, deactivation of single “jexels” is iteratively performed, starting with the best pattern found at G51 (which is the same pattern of G30). Since the initial configuration had 21 “jexels” active, a total of Σₙ₌₁²¹ n=231 evaluations were necessary to complete the clean-up procedure.

Specifically, the inherent randomness of the GA is known to produce results that are difficult to interpret. To improve interpretability and draw better conclusions about what the solution found by the GA is doing, a clean-up procedure was performed after convergence of the GA. This clean-up procedure is necessary because there could be many “jexels” in the best configurations that do not have a significant effect on the cost function, but did not get removed by the GA due to random chance or the limitation in the number of iterations performed. This step, therefore, is crucial to draw a deeper understanding from the results.

Starting with the “BestIndividual” configuration, the following pseudocode was used:

```
CurrentIndividual ← BestIndividual;
for j ← 1 to BestIndividual.nJexels do
  for i ← 1 to CurrentIndividual.nJexels do
    TestIndividual ← CurrentIndividual;
    TestIndividual.RemoveJexel(i);
    Cost(i)=TestIndividual.EvaluateCostFunction();
  end
  Find K that minimizes Cost(K);
  CurrentIndividual.RemoveJexel(K);
end
```

Following this procedure enabled assessment of the contribution of each individual “jexel” to the obtained solution, slowly removing one “jexel” at a time and observing how relevant its contribution was. Accordingly, many of the “jexels” produced by the GA could be removed without reducing the solution fitness, unveiling a reasonably interpretable pattern.

The iterative deactivation allows for definition of which “jexels” are effectively contributing to the results obtained, versus “jexels” that were left active because their contribution to the overall performance is neither positive nor negative, in which case they are only consuming actuation power.

Prior to the clean-up, it is important to address the fact that the GA preferred higher frequencies and higher duty cycles in the solution. This observation led the authors to believe the algorithm exploited the bandwidth limits of the solenoid valve setup. If the momentum flux was the underlying variable that increased performance, it is far more likely, given the randomness of the GA, that the GA will accomplish increases in average momentum flux by increasing both the frequency and duty cycle than by associating the blowing frequency to exactly 0 Hz. Since the frequency was defined as an integer-valued variable, there was a 1/200 chance of using a steady blowing frequency, which is much lower than the ˜1/4 chance of being in the upper end (150 to 200 Hz) where this phenomenon has a significant impact. A posterior study with a mass flow meter confirmed that the mass flow rate \dot{m}_{200 Hz}=0.85\dot{m}_{DC} at 50% duty cycle, where \dot{m}_{DC}=2.26 SLPM/jexel at P_{B}=7.5 psi.

Due to this observed behavior, the blowing frequency was reset to 0 Hz for the remaining part of this study. The circulation change measured with the 4-hole probe with DC blowing was ΔΓ/Γ=−11.5%, which is effectively no change compared to the original GA solution, given the measurement uncertainty, as shown in FIG. 7.

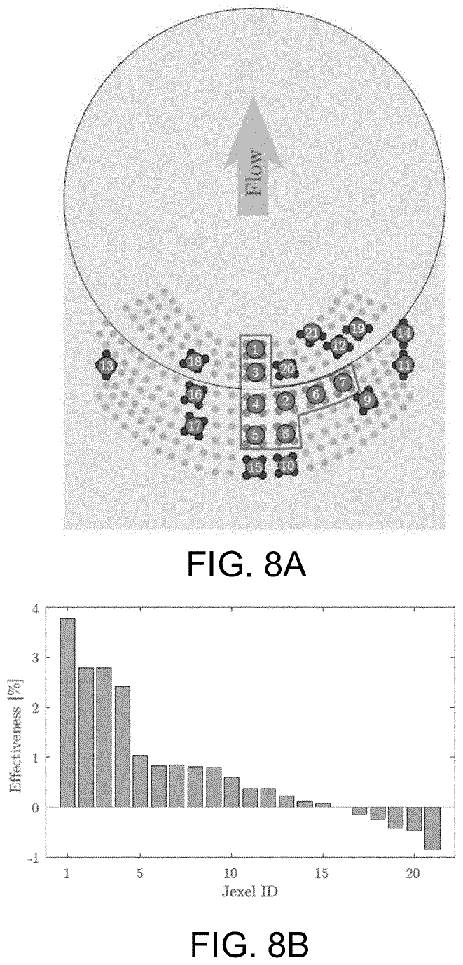

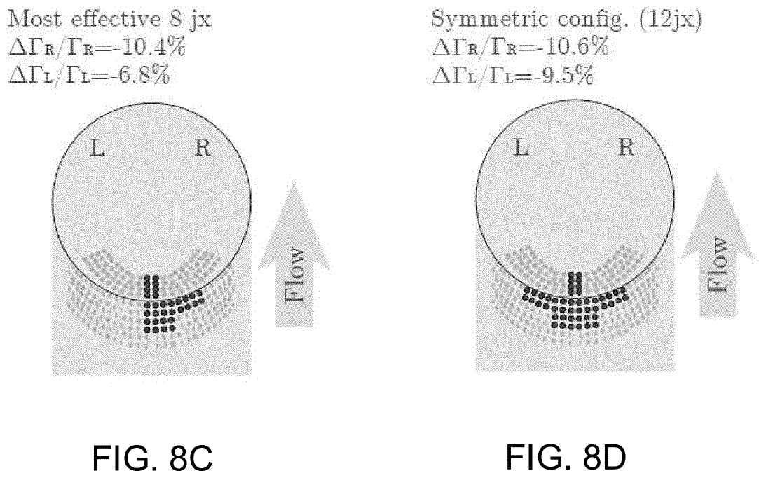

The results obtained by the clean-up procedure are summarized in FIGS. 8A-8C. The “jexel” pattern obtained in Generation 51 is shown in more detail in FIG. 8A, where the “jexels” are numbered according to their effectiveness (lowest number=highest effectiveness). A high effectiveness “jexel” is defined as one that causes a large loss in overall performance when deactivated. For example, the “jexel” ranked #1 (ID=1) caused an increase in circulation of 3.8% when turned off, meaning it is the most important “jexel” in the configuration. The “jexels” were then organized by this metric, as shown in FIG. 8B. The lowest ranked “jexels” were found to have a slightly negative contribution to the performance beyond measurement uncertainty, i.e., their effect is of increasing circulation. Curiously, their location is very close to the most effective “jexels,” which is a clear indicator of how the microjet-in-crossflow actuator placement problem is not straightforward. The 8 most effective “jexels” were then picked for further study with Particle Image Velocimetry (NV). Their pattern is highlighted in both FIG. 8A as a thin outline and plotted explicitly in FIG. 8C.

An alternative symmetric configuration was also evaluated with PIV, whose pattern is shown in FIG. 8D. The circulation values in FIGS. 8C and 8D summarize the PIV observations, where the asymmetric pattern did affect the right vortex to a similar extent as measured by the four-hole probe, to a 1% difference. The left vortex in the asymmetric configuration, however, was not affected nearly as much. This evidences how the GA biased its solution to maximize the effect where the measurement was performed, a cautionary of performing optimization with partial measurements that do not capture the complete and relevant flow response. The symmetric pattern, however, corrects for that effect and the measured changes in circulation are effectively the same for both vortices. Symmetry could have been enforced in the hardware design step; however, the authors also were interested in confirming that asymmetric configurations are indeed less attractive.

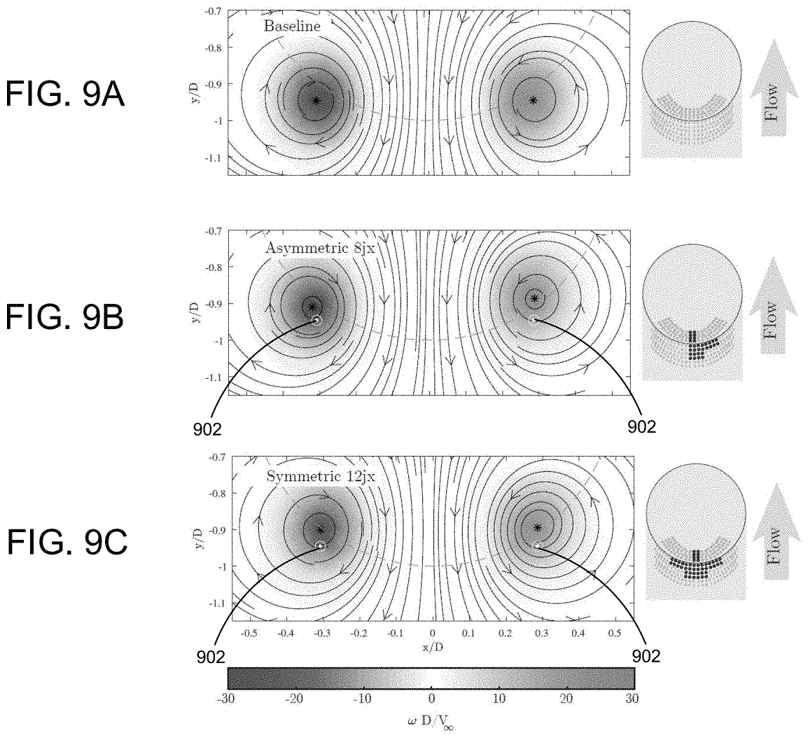

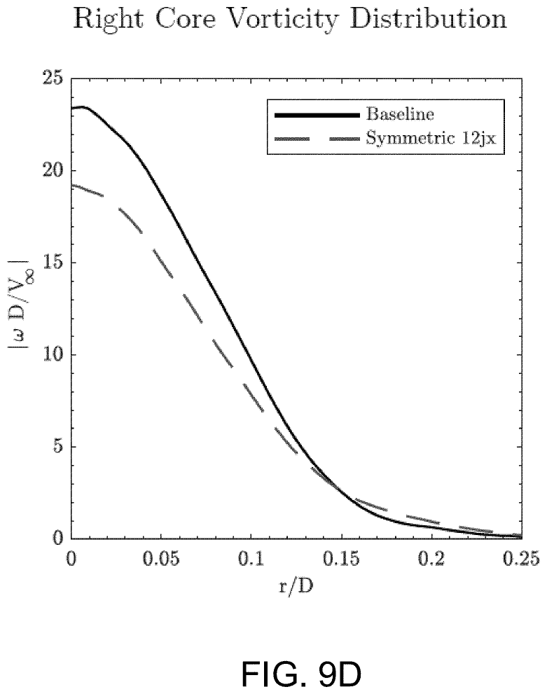

FIGS. 9A-9C illustrate vorticity fields observed through SPIV for the three configurations examined. The black stars indicate vortex core tracked by peak Γ₁, the circled yellow dots 902 show baseline case vortex core locations, and the red dashed line indicates position of the cylindrical body. The mean PIV vector field of the baseline case is illustrated in FIG. 9A as streamlines overlaid on vorticity contours. It is presented against the two actuated cases previously discussed in FIGS. 9B and 9C. The PIV fields show a significant displacement of the vortex core, as can be inferred from comparing the black stars against circled yellow dots 902 (baseline core locations). For the asymmetric actuator case in FIG. 9B, the right vortex core (on the actuator side) was displaced significantly more than the left core. As expected, the symmetric case presented a similar displacement of the core for both sides. The displacement of the core was directed upwards by about 0.05D, which corresponds to 7.5 mm in physical space. It is consistent with the observed weakening of the vortices, since the induced velocity of one vortex on the other is reduced, causing less vertical displacement of the cores as they move downstream. Interestingly, the reduction in vortex strength does not seem to be related to increased diffusion of the core, since in the comparison of vorticity distribution shown in FIG. 9D, an overall reduction in vorticity as a function of radius is observed. In other words, the vortex is not being weakened by increasing the core size through diffusion, but by prevention of vorticity production at the base of the body.

Up to the current stage of this study, however, it is not clear what exactly was the effect of the microjets in the flow field that prevented vorticity from being produced. It is fair to conjecture that the microjets in the cylindrical portion of the model are manipulating the boundary layer. The microjets downstream of the edge, at the flat section of the slanted surface, might be substantially interfering with the separation bubble dynamics, perhaps shrinking it. Since the separation bubble has been shown to be connected to the pair of vortices in this flow field, it is likely that changes in its topology might affect the dynamics of the vortex pair, possibly even its formation process. The actuation strategy found by the GA, however, is completely novel in the context of bluff body wake control and is not straightforward to define a priori, especially when one considers that “jexel” IDs #18 and #20 in FIG. 8A, which are also inside the separation bubble, had measurably the opposite effect as “jexels” #1 and #3. More importantly, the solution obtained has proven to be much more effective than the paradigm of line-shaped arrays of jets, which has become a de-facto standard when it comes to “informed ad-hoc” studies.

It is important to acknowledge, however, that the solution obtained might still not be ideal from an engineering standpoint. Due to the way the cost function was defined, the algorithm greedily reduced circulation, with complete disregard to the amount of power necessary to operate the jets. The momentum and power coefficients (C_{μ} and C_{π}) of each “jexel” are given below:

$${C}_{μ} = \frac{Jexel Momentum}{Model Drag} = \frac{{ρ}_{jet} {u}_{jet}^{2} {A}_{jet}}{0.5 {C}_{D} {ρ}_{∞} {V}_{∞}^{2} {A}_{model}} = 5.3 \times {10}^{- 3} / jexel$$

$${C}_{π} = \frac{Jexel Power}{Model Drag Power} = \frac{0.5 {ρ}_{jet} {u}_{jet}^{3} {A}_{jet}}{0.5 {C}_{D} {ρ}_{∞} {V}_{∞}^{3} {A}_{model}} = 1.93 \times {10}^{- 2} / jexel$$

Where the values provided were obtained through a mass flow meter measurement to determine the “jexel” mass flow rate, and correspond to a back-pressure of P_{B}=7.54 psi, which was the back-pressure found by the GA. The normalization by the model drag and drag power, respectively, is used to improve the physical interpretability. For C_{π}, for example, the value obtained means every single “jexel” (i.e., group of 4 microjets) would have to reduce the drag power by 1.93% to pay for its energy cost. Unfortunately, the solution found in this study did not attain net positive power savings, since its cleaned-up, symmetric configuration employs 12 “jexels,” meaning it requires 23.2% of the drag power to be operated, while only reducing drag by 10.6% (inferred from SPIV circulation measurements). Therefore, the “jexel” configuration obtained in this study has an expected power increase of ΔP/P=+12.6%. It might be possible to further reduce the power requirement by having finer control over each of the four microjets within each “jexel,” which would be feasible with increased complexity in the initial study or with a follow-up, targeted study. Since the cost function defined at the start of this study did not include power savings as an objective, the fact that the optimal configuration obtained did not achieve net power savings is not surprising. The optimization technique demonstrated in this study, however, is likely capable of finding a net positive power savings solution provided that was the initial objective of the algorithm.

Accordingly, in this study, a new type of test bed was developed and deployed to find a solution to the microjet-in-crossflow actuator placement problem. A genetic algorithm was employed to explore the high dimensional, combinatorial parameter space. About 2000 different “jexel” configurations were explored, along with an additional 600 configurations on auxiliary studies to confirm the variables that were observed. The number of spatial “jexel” patterns explored in this study is by far the largest ever experimentally accomplished in a single study, to the knowledge of the authors, which evidences that this technique can add a new perspective to practical studies in actuator placement.

The initial focus of this study was an implementation in the slanted cylinder wake problem at an angle of 45°, and the results are very encouraging. The reduction in circulation measured, which is a proxy for drag in this model, was of 10.6% as measured by PIV. The solution found by the Genetic Algorithm was about three times more effective than the most effective solution (3.5%) defined manually with a similar number of active microactuators. This result demonstrates not only the strength of the optimization approach, but also how important it is to have flexibility in the location of the microactuators in this type of study. The physical mechanisms that the GA exploited to produce the result observed are yet to be fully understood. It is possible that the main mechanisms are boundary layer energization and modification of the separation bubble which, due to its strong coupling to the vortex pair could have prevented vorticity from being generated at the base of the model. The solution found in this study did not generate net power savings, as that was not the objective defined in this study. However, an appropriately defined cost function or objective will likely yield such an outcome. More generally, the technique presented herein can be very useful for finding practical engineering answers to the actuator placement problem, as well as improving the general understanding of the flow control problem when complex base geometries are involved.

While various illustrative embodiments of the invention are described above, it will be apparent to one skilled in the art that various changes and modifications may be made therein without departing from the invention. For example, the systems and methods described herein may be deployed to any engineering problem of external or internal aerodynamics (i.e., cars, trucks, trains, aircraft, ducts, etc.) where active flow control is a desirable technology but finding the best configuration of actuators is currently an intractable problem. The appended claims are intended to cover all such changes and modifications that fall within the true scope of the invention.

What is claimed:

1. A system for determining optimized placement and operating conditions of active flow control actuators, the system comprising:
a plurality of active flow control actuators spatially distributed within a flow field, each of the plurality of active flow control actuators configured to be individually actuated;
one or more sensors configured to measure one or more parameters within the flow field; and
a non-transitory computer readable medium programmed with instructions that, when executed by a processor of a computer, cause the computer to:
execute an optimization routine to sequentially activate varying subsets of active flow control actuators of the plurality of active flow control actuators;
calculate a cost function of each of the subsets of sequentially activated active flow control actuators based on respective measurements of the one or more parameters by the one or more sensors within the flow field; and
determine an optimal subset of active flow control actuators based on the respective cost functions of each of the subsets of sequentially activated active flow control actuators.

2. The system of claim 1, wherein at least one of position or one or more operating conditions of one or more active flow control actuators are configured to vary across each subset of sequentially actuated active flow control actuators, such that the determined optimal subset of active flow control actuators comprises a combination of optimal placement and optimal operating conditions.

3. The system of claim 2, wherein the one or more operating conditions comprise at least one of amplitude, phase, or frequency for each individual active flow control actuator.

4. The system of claim 1, wherein each subset of sequentially actuated active flow control actuators comprises one or more active flow control actuators, each of the one or more active flow control actuators comprising a predefined position and one or more predefined operating conditions.

5. The system of claim 1, wherein the varying subsets of active flow control actuators are selected at random by the optimization routine.

6. The system of claim 1, wherein the varying subsets of active flow control actuators are selected in a predetermined manner by the optimization routine.

7. The system of claim 1, wherein each active flow control actuator of the plurality of active flow control actuators is a jexel comprising one or more microjets.

8. The system of claim 1, wherein the one or more parameters within the flow field comprises integral variables or proxies to the integral variables within the flow field.

9. The system of claim 8, wherein the integral variables comprise at least one of drag, lift, noise, or energy consumption.

10. The system of claim 1, wherein the optimization routine comprises a genetic algorithm that, when executed:
is initialized with a randomly chosen or a manually defined set of actuator configurations;
sequentially activates a first generation of varying subsets of active flow control actuators of the plurality of active flow control actuators;
calculates the cost function of each of the subsets of sequentially activated active flow control actuators based on the respective measurements of the one or more parameters by the one or more sensors within the flow field; and
iteratively generates subsequent generations of varying subsets of active flow control actuators of the plurality of active flow control actuators based on the cost functions of each of the subsets of sequentially activated active flow control actuators of a previous generation to thereby determine the optimal subset of active flow control actuators.

11. The system of claim 10, wherein the genetic algorithm, when executed, iteratively generates subsequent generations of varying subsets of active flow control actuators of the plurality of active flow control actuators by:
selecting an elite group of subsets from a current generation of the varying subsets of active flow control actuators based on the respective cost functions;
mutating each subset of the elite group of subsets through a set of operations over one or more operating conditions of the plurality of active flow control actuators; and
generating a subsequent generation of varying subsets of active flow control actuators based on randomly selected mutated subsets.

12. The system of claim 11, wherein mutating each subset of the elite group of subsets comprises executing operations selected from a list consisting of: change active flow control actuators count, change active flow control actuators addresses, change active flow control actuators frequency, change active flow control actuators phases, change active flow control actuators duty cycles, and change back-pressure.

13. The system of claim 11, wherein generating the subsequent generation of varying subsets of active flow control actuators based on randomly selected mutated subsets comprises:
randomly selecting a pair of mutated subsets;
copying a genome of a first mutated subset of the pair of mutated subsets; and
swapping a randomly selected portion of the copied genome with a randomly selected portion of a genome of a second mutated subset of the pair of mutated subsets.

14. The system of claim 11, wherein the optimization routine further comprises executing a clean-up operation on the optimal subset of active flow control actuators by iteratively deactivating an active flow control actuator of the optimal subset of active flow control actuators to assess contribution of the deactivated active flow control actuator.

15. The system of claim 1, wherein the flow field is representative of an aerodynamic body.

16. The system of claim 15, wherein the aerodynamic body comprises an aerial vehicle, a land vehicle, an aquatic vehicle, or their components.

17. The system of claim 1, wherein the flow field is representative of a turbomachine.

18. The system of claim 17, wherein the turbomachine comprises a compressor, fan, or turbine.

19. A computerized method for determining optimized placement and operating conditions of active flow control actuators, the computerized method comprising:
executing an optimization routine to sequentially activate varying subsets of active flow control actuators of a plurality of active flow control actuators spatially distributed within a flow field;
calculating a cost function of each of the subsets of sequentially activated active flow control actuators based on respective measurements of one or more parameters within the flow field by one or more sensors; and
determining an optimal subset of active flow control actuators based on the respective cost functions of each of the subsets of sequentially activated active flow control actuators.

20. The computerized method of claim 19, wherein at least one of position or one or more operating conditions of one or more active flow control actuators are configured to vary across each subset of sequentially actuated active flow control actuators, such that determining the optimal subset of active flow control actuators comprises determining a combination of optimal placement and optimal operating conditions.
